(19) United States
(12) Patent Application Publication
(10) Pub. No.: US 2008/0237618 A1
(43) Pub. Date: Oct. 2, 2008

(54) LIGHT EMITTING DIODE MODULE AND MANUFACTURING METHOD THEREOF

(76) Inventors: Feng-Fu Ko, Taipei City (TW); Ching-Yi Wei, Taipei County (TW); Jin-Lien Chen, Keelung City (TW)

Correspondence Address: NORTH AMERICA INTELLECTUAL PROPERTY CORPORATION, P.O. BOX 506, MERRIFIELD, VA, 22116, US

(21) Appl. No.: 11/690,857

(22) Filed: Mar. 26, 2007

(51) Int. Cl. H01L 33/00

(52) U.S. Cl. 257/98; 438/27; 257/E33.057

(57) ABSTRACT

A light emitting diode (LED) module. The LED module includes: an LED chip, for emitting a light beam; a packaging structure, for packaging the LED chip; and a light direction changing unit, connected to the packaging structure, for changing a direction of the light beam, wherein the light direction changing unit has a base material and at least a photoluminescent material, and the photoluminescent material is mixed within the base material to form the light direction changing unit.

### BACKGROUND OF THE INVENTION

1. Field of the Invention

The present invention relates to a light emitting diode (LED) module, and more particularly, to an LED module and a manufacturing method thereof.

2. Description of the Prior Art

Light emitting diode (LED) chips are very common electronic components in present markets. Since LED chips are unable to emit white light by themselves physically, some photoluminescent material is required to work with the LED chips for producing white light. Additionally, light beams emitted from an LED chip in a conventional LED module often have the problem of improperly big color temperature difference between inner and outer light circles. Therefore, how to effectively dispose the photoluminescent material in the LED module to make light beams from the LED chip more even is a desired and considerable topic.

### SUMMARY OF THE INVENTION

It is therefore one of the objectives of the present invention to provide a light emitting diode (LED) module and a manufacturing method thereof to solve the above mentioned problems.

According to one embodiment of the present invention, the present invention discloses an LED module, comprising: an LED chip, for emitting a light beam; a packaging structure, for packaging the LED chip; and a light direction changing unit, connected to the packaging structure, for changing a direction of the light beam, wherein the light direction changing unit has a base material and at least a photoluminescent material, and the photoluminescent material is mixed within the base material to form the light direction changing unit.

According to another embodiment of the present invention, the present invention discloses a manufacturing method of an LED module, comprising: providing an LED chip, a base material, and at least a photoluminescent material, wherein the LED chip emits a light beam; packaging the LED chip to form a packaging structure; and mixing the photoluminescent material within the base material to form a light direction changing unit; and connecting the light direction changing unit to the packaging structure, wherein the light direction changing unit changes a direction of the light beam.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a structural diagram illustrating an LED module according to an embodiment of the present invention.

FIG. 2 is a flowchart illustrating a manufacturing method of an LED module according to an embodiment of the present invention.

FIG. 3 is a flowchart illustrating details of a forming step of a light direction changing unit in FIG. 2.

### DETAILED DESCRIPTION

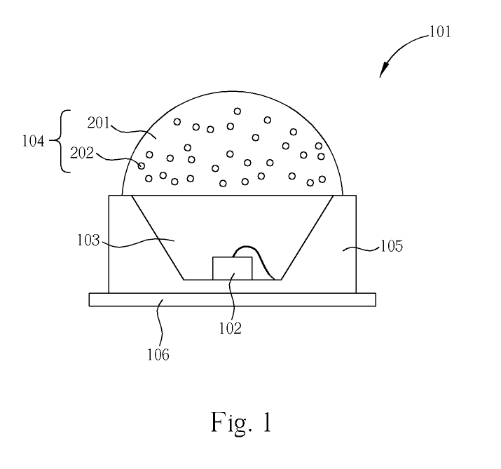

FIG. 1 is a structural diagram illustrating a light emitting diode (LED) module 101 according to an embodiment of the present invention. As shown, the LED module 101 comprises an LED chip 102, a packaging structure 103, a light direction changing unit 104, a substrate 105, and a circuit board 106. The LED chip 102 is disposed on the substrate 105 for emitting a light beam. The substrate 105 is soldered onto the circuit board 106. The packaging structure 103 packages the LED chip 102. The light direction changing unit 104 is connected to the packaging structure 103 for changing a direction of the light beam emitted from the LED chip 102. Additionally, the light direction changing unit 104 has a base material 201 and at least a photoluminescent material 202. Please note that the LED module 101 has more components, but only the components related to the present invention are shown in FIG. 1. Additionally, the structure, shape, and dimension of the LED module 101 as shown in FIG. 1 are merely one example of the present invention and thus are not meant to be a limitation of the present invention. After understanding the principles of the present invention, those skilled in the art can easily design different structure, shape, and dimension for the LED module 101. Those possible alternative designs all fall in the scope of the present invention.

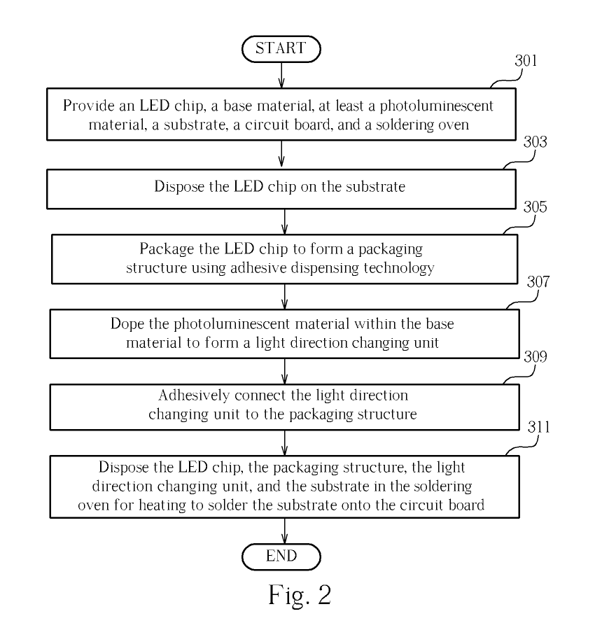

FIG. 2 is a flowchart illustrating a manufacturing method of the LED module 101 according to an embodiment of the present invention. As shown, the manufacturing method comprises the following steps:

STEP 301: Provide an LED chip, a base material, at least a photoluminescent material, a substrate, a circuit board, and a soldering oven;

STEP 303: Dispose the LED chip on the substrate;

STEP 305: Package the LED chip to form a packaging structure using adhesive dispensing technology;

STEP 307: Dope the photoluminescent material within the base material to form a light direction changing unit;

STEP 309: Adhesively connect the light direction changing unit to the packaging structure; and

STEP 311: Dispose the LED chip, the packaging structure, the light direction changing unit, and the substrate in the soldering oven for heating to solder the substrate onto the circuit board.

The detailed description as to how the LED module 101 in FIG. 1 is manufactured using the manufacturing method in FIG. 2 is as follows.

First, an LED chip 102, a base material 201, at least a photoluminescent material 202, a substrate 105, a circuit board 106, and a soldering oven (not shown in drawings) are provided (STEP 301). In this embodiment, the base material 201 is an engineering plastic material, such as a silicone or an epoxy resin. The photoluminescent material 202 is a phosphor. The circuit board 106 is a metal core printed circuit board (MCPCB). The soldering oven is an IR-reflow oven. Next, the LED chip 102 is disposed on the substrate 105 (STEP 303). The LED chip 102 is packaged to form a packaging structure 103 using adhesive dispensing technology (STEP 305). The photoluminescent material 202 is doped within the base material 201 to form a light direction changing unit 104 (STEP 307). The light direction changing unit 104 is then adhesively connected to the packaging structure 103 (STEP 309). Additionally, in this embodiment, any connecting portion of the light direction changing unit 104 connected to the packaging structure 103 is substantially on the same plane, as shown in FIG. 1. Finally, the LED chip 102, the packaging structure 103, the light direction changing unit 104, and the substrate 105 are disposed in the soldering oven for heating to solder the substrate 105 onto the circuit board 106 (STEP 311). The process ends herein. Please note that, in this embodiment, a thermal deformation temperature of the base material 201 is higher than a heating temperature of the soldering oven, so the light direction changing unit 104 can be safely disposed in the soldering oven without any deformation or damage. Additionally, in this embodiment, the heating temperature of the soldering oven is 260° C. This is not meant to be a limitation of the present invention, however.

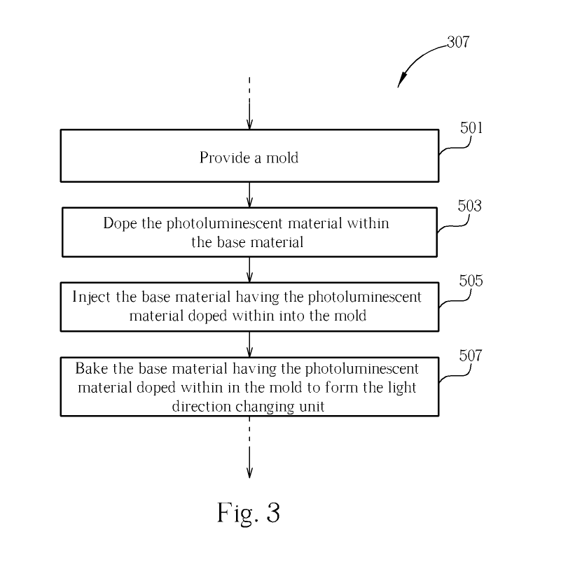

FIG. 3 is a flowchart illustrating details of the forming step (i.e. STEP 307) of the light direction changing unit 104 in FIG. 2. As shown, STEP 307 of FIG. 2 comprises the following steps:

STEP 501: Provide a mold;

STEP 503: Dope the photoluminescent material within the base material;

STEP 505: Inject the base material having the photoluminescent material doped within into the mold; and

STEP 507: Bake the base material having the photoluminescent material doped within in the mold to form the light direction changing unit.

As shown in FIG. 3, first, a mold (not shown in drawings) is provided (STEP 501). Moreover, the mold is determined according to a desired shape of the light direction changing unit 104. The desired shape, for example, can be a hemisphere, a sphere, or a single convex. Next, the photoluminescent material 202 is doped within the base material 201 (STEP 503). The base material 201 having the photoluminescent material 202 doped within is then injected into the mold (STEP 505). Finally, the base material 201 having the photoluminescent material 202 doped within in the mold is baked to form the light direction changing unit 104 having the desired shape of a hemisphere, a sphere, or a single convex substantially (STEP 507). Additionally, in this embodiment, the light direction changing unit 104 is an optical lens having the photoluminescent material 202.

In the present invention, a photoluminescent material is doped within a base material to form a light direction changing unit (i.e. optical lens). Therefore, when a light beam emitted from an LED chip travels through the light direction changing unit, not only its direction is changed by the light direction changing unit, but also it is scattered after randomly hitting the photoluminescent material in the base material, thereby avoiding the problem of improperly big color temperature difference between inner and outer light circles in the prior art. Simply speaking, an LED module of the present invention can produce more even light beams than before. Additionally, the base material of the present invention is a high temperature-resistant material. Specifically, the base material has a thermal deformation temperature higher than a heating temperature of a soldering oven. Therefore, the light direction changing unit can be safely disposed in the soldering oven without any deformation or damage during the process of manufacturing the LED module of the present invention. Accordingly, the LED module of the present invention can be manufactured using full automatic surface mount technology (SMT). Furthermore, a substrate having an LED chip disposed thereon can be soldered onto a circuit board automatically in a mass production manner, thereby greatly reducing required labor power in manufacture.

Those skilled in the art will readily observe that numerous modifications and alterations of the device and method may be made while retaining the teachings of the invention.

What is claimed is:

1. A light emitting diode (LED) module, comprising:
an LED chip, for emitting a light beam;
a packaging structure, for packaging the LED chip; and
a light direction changing unit, connected to the packaging structure, for changing a direction of the light beam, wherein the light direction changing unit has a base material and at least a photoluminescent material, and the photoluminescent material is mixed within the base material to form the light direction changing unit.

2. The module of claim 1, wherein the packaging structure packages the LED chip using adhesive dispensing technology.

3. The module of claim 1, wherein the light direction changing unit is connected to the packaging structure after the packaging structure has packaged the LED chip.

4. The module of claim 1, wherein the light direction changing unit is adhesively connected to the packaging structure.

5. The module of claim 1, wherein any connecting portion of the light direction changing unit connected to the packaging structure is substantially on the same plane.

6. The module of claim 1, wherein the light direction changing unit is substantially hemispherical, spherical, or single convex.

7. The module of claim 1, wherein the light direction changing unit is an optical lens having the photoluminescent material.

8. The module of claim 1, wherein the base material is an engineering plastic material, the photoluminescent material is a phosphor, and the photoluminescent material is doped within the base material to form the light direction changing unit.

9. The module of claim 8, wherein the engineering plastic material is a silicone or an epoxy resin.

10. The module of claim 1, wherein, further comprising:
a substrate; and
a circuit board;
wherein the LED chip is disposed on the substrate, the substrate is soldered onto the circuit board through a soldering oven, and a thermal deformation temperature of the base material is higher than a heating temperature of the soldering oven.

11. The module of claim 10, wherein the circuit board is a metal core printed circuit board (MCPCB).

12. The module of claim 10, wherein the soldering oven is an IR-reflow oven.

13. A manufacturing method of an LED module, comprising:
providing an LED chip, a base material, and at least a photoluminescent material, wherein the LED chip emits a light beam;
packaging the LED chip to form a packaging structure;
mixing the photoluminescent material within the base material to form a light direction changing unit; and
connecting the light direction changing unit to the packaging structure, wherein the light direction changing unit changes a direction of the light beam.

14. The method of claim 13, wherein the step of packaging the LED chip to form the packaging structure comprises:
packaging the LED chip to form the packaging structure using adhesive dispensing technology.

15. The method of claim 13, wherein the step of connecting the light direction changing unit to the packaging structure is performed after the step of packaging the LED chip to form the packaging structure is completed.

16. The method of claim 13, wherein the step of connecting the light direction changing unit to the packaging structure comprises:
adhesively connecting the light direction changing unit to the packaging structure.

17. The method of claim 13, wherein the base material is an engineering plastic material, the photoluminescent material is a phosphor, and the step of mixing the photoluminescent material within the base material to form the light direction changing unit comprises:
doping the phosphor within the engineering plastic material to form the light direction changing unit.

18. The method of claim 17, wherein the engineering plastic material is a silicone or an epoxy resin.

19. The method of claim 13, wherein the step of mixing the photoluminescent material within the base material to form the light direction changing unit comprises:
providing a mold;
doping the photoluminescent material within the base material;
injecting the base material having the photoluminescent material doped within into the mold; and
baking the base material having the photoluminescent material doped within in the mold to form the light direction changing unit.

20. The method of claim 13, further comprising:
providing a substrate, a circuit board, and a soldering oven;
disposing the LED chip on the substrate; and
soldering the substrate onto the circuit board through the soldering oven;
wherein a thermal deformation temperature of the base material is higher than a heating temperature of the soldering oven.

21. The method of claim 20, wherein the circuit board is an MCPCB.

22. The method of claim 20, wherein the soldering oven is an IR-reflow oven.

23. The method of claim 20, wherein the step of soldering the substrate onto the circuit board through the soldering oven comprises:
disposing the LED chip, the packaging structure, the light direction changing unit, and the substrate in the soldering oven for heating to solder the substrate onto the circuit board.
